(19) United States
(12) Patent Application Publication
(10) Pub. No.: US 2015/0255186 A1
(43) Pub. Date: Sep. 10, 2015

(54) BASE MATERIAL WITH A TRANSPARENT CONDUCTIVE FILM, METHOD FOR MANUFACTURING THE SAME, TOUCH PANEL, AND SOLAR CELL

(71) Applicant: Panasonic Intellectual Property Management Co., Ltd., Osaka (JP)

(72) Inventors: AKIRA TSUJIMOTO, Nara (JP); TAKASHI ICHIRYU, Osaka (JP); KAZUMA MIMA, Osaka (JP)

(21) Appl. No.: 14/626,937

(22) Filed: Feb. 20, 2015

(30) Foreign Application Priority Data
Mar. 6, 2014 (JP) 2014-043422

(51) Int. Cl. H01B 1/22; C23F 1/00; C23F 1/16; H05K 1/09; H01L 31/0224

(52) U.S. Cl. CPC H01B 1/22; H05K 1/092; H01L 31/022466; C23F 1/16; C23F 1/00

(57) ABSTRACT

A aspect of the present disclosure provides a base material with a transparent conductive film on or above the base material. The transparent conductive film includes a conductive layer containing metal wires, and a protective layer being located on a side of the conductive layer and containing a resin and a particle, the side not opposing to the base material. The particle is soluble in an acidic etching solution, and the resin is resistant to the acidic etching solution.

### CROSS REFERENCES TO RELATED APPLICATIONS

This application claims priority to Japanese Patent Application No. 2014-043422, filed on Mar. 6, 2014, the contents of which are hereby incorporated by reference.

### BACKGROUND

1. Technical Field

The resent disclosure relates to a base material with a transparent conductive film, method for manufacturing the same, touch panel, and solar cell.

2. Description of the Related Art

Transparent conductive films which are transparent and conductive are widely used as electrodes for organic electroluminescent devices (OELDs), liquid crystal displays, solar cells, and other devices.

In recent years, conductive layers containing thin metal wires have been proposed as transparent conductive films. For example, Japanese Unexamined Patent Application Publication No. 2011-198736 (hereinafter referred to as Patent Literature 1) and Japanese Unexamined Patent Application Publication (Translation of PCT Application) No. 2009-505358 (hereinafter referred to as Patent Literature 2) each disclose a conductive layer containing thin metal wires and a method for patterning the conductive layer.

Patent Literature 1 discloses a photosensitive conductive film including a support, conductive layer, and photosensitive resin layer stacked in that order. The photosensitive resin layer and the conductive layer of the photosensitive conductive film are laminated (reverse-transferred) on a substrate, whereby the photosensitive resin layer and the conductive layer are stacked on the substrate in that order. The photosensitive conductive film is selectively cured by pattern exposure and an uncured portion of the photosensitive resin layer and a corresponding portion of the conductive layer are removed, whereby a non-conductive portion is formed.

Patent Literature 2 discloses a configuration including a transparent substrate and a conductive layer which is placed on the transparent substrate and which is composed of metal nanowires and a photosensitive resin. The photosensitive resin of the conductive layer is selectively cured and an uncured portion of the conductive layer is removed, whereby a non-conductive portion is formed.

On the other hand, in order to enhance durability, a configuration including a conductive layer containing thin metal wires and a protective layer placed on the conductive layer has been proposed. For example, International Publication No. 2011/081023 (hereinafter referred to as Patent Literature 3) discloses a transparent conductive film including a conductive layer and a protective layer stacked thereon. In Patent Literature 3, the conductive layer is patterned in such a manner that a removal agent is provided on a predetermined region of the protective layer by printing and the protective layer and the conductive layer are partly removed using the removal agent, whereby a non-conductive portion is formed.

However, in the configuration including the conductive layer containing the thin metal wires and the protective layer placed thereon, a patterning method needs to be further improved from the viewpoint of the ease of production and the precision of patterns.

### SUMMARY

One non-limiting and exemplary embodiment provides a base material with a transparent conductive film having a structure in which a protective layer is placed on a conductive layer containing thin metal wires. The conductive layer can be readily and precisely patterned.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

In one general aspect, the techniques disclosed here feature a base material with a transparent conductive film on or above the base material. The transparent conductive film includes a conductive layer containing metal wires, and a protective layer being located on a side of the conductive layer and containing a resin and a particle, the side not opposing to the base material. The particle is soluble in an acidic etching solution, and the resin is resistant to the acidic etching solution.

These general and specific aspects may be implemented using a base material with a transparent conductive film, a touch panel, a solar cell, an electronic device, a system, a method, and any combination of a base material with a transparent conductive films, touch panels, solar cells, electronic devices, systems, and methods.

In accordance with a base material with a transparent conductive film according to the present disclosure, photolithography can be used to pattern a conductive layer in spite of that a protective layer is placed on the conductive layer. Thus, the conductive layer can be readily and precisely patterned.

### BRIEF DESCRIPTION OF THE DRAWINGS

FIG. 1 is a sectional view of a base material with a transparent conductive film according to an embodiment of the present disclosure;

FIG. 2A is a sectional view showing a step of a method for manufacturing a base material with a transparent conductive film including a conductive portion and a non-conductive portion according to an embodiment of the present disclosure;

FIG. 2B is a sectional view showing a step of the method for manufacturing the base material with a transparent conductive film including a conductive portion and a non-conductive portion;

FIG. 2C is a sectional view showing a step of the method for manufacturing the base material with a transparent conductive film including a conductive portion and a non-conductive portion;

FIG. 2D is a sectional view showing a step of the method for manufacturing the base material with a transparent conductive film including a conductive portion and a non-conductive portion;

FIG. 2E is a sectional view showing a step of the method for manufacturing the base material with a transparent conductive film including a conductive portion and a non-conductive portion;

FIG. 2F is a sectional view showing a step of the method for manufacturing the base material with a transparent conductive film including a conductive portion and a non-conductive portion;

FIG. 3 is a sectional view of a touch panel according to an embodiment of the present disclosure;

FIG. 4 is a sectional view of a solar cell according to an embodiment of the present disclosure; and

FIG. 5 is a sectional view of a solar cell according to another embodiment of the present disclosure.

### DETAILED DESCRIPTION

The inventors have found that the techniques, described in Patent Literatures 1 to 3, for patterning a conductive layer containing thin metal wires as described in the paragraphs entitled “Description of the Related Art” have room for improvement in readily and precisely performing patterning. Furthermore, the inventors have found problems below as a result of intensive investigation.

The technique described in Patent Literatures 1 needs to laminate the photosensitive resin layer on another base material as described above. Thus, the technique described in Literature 1 is complicated in process. Furthermore, there are problems, such as pasting precision and dust catching, relating to yield. Furthermore, in the non-conductive portion, the photosensitive resin layer and the conductive layer are partly removed. Thus, there is a problem in that a step between the non-conductive portion and a conductive portion is large and therefore a pattern is conspicuous. Furthermore, there is a problem with the durability of metal nanowires in the conductive layer because the conductive layer is outermost and is exposed after the pattern is formed.

In the technique described in Patent Literature 2, when a pattern is formed in the conductive layer, the non-conductive portion of the conductive layer is removed. Thus, there is a problem in that a step between the non-conductive portion and a conductive portion is large and therefore the pattern is conspicuous.

In the technique described in Patent Literature 3, the removal agent for etching the protective layer is applied to the protective layer by printing. Thus, it is difficult to precisely form a high-definition pattern in the conductive layer.

Therefore, the inventors have investigated the problems with the techniques described in Patent Literatures 1 to 3 to provide a base material with a transparent conductive film according to the present disclosure as described below. Furthermore, the inventors provide a base material with a transparent conductive film including a conductive portion and a non-conductive portion according to the present disclosure, a method for manufacturing the same, a touch panel according to the present disclosure, and a solar cell according to the present disclosure.

A first aspect of the present disclosure provides a base material with a transparent conductive film on or above the base material. The transparent conductive film includes a conductive layer containing metal wires, and a protective layer being located on a side of the conductive layer and containing a resin and a particle, the side not opposing to the base material. The particle is soluble in an acidic etching solution, and the resin is resistant to the acidic etching solution.

In the base material with a transparent conductive film according to the first aspect, the protective layer is placed on the conductive layer and contains the particles, which are soluble in the acidic etching solution, and the resin, which is resistant to the acidic etching solution. Exposing the protective layer to the acidic etching solution allows the resin to remain in the protective layer and also allows the particles to be removed from the protective layer by dissolving the particles in the acidic etching solution. Thus, the particles can be removed from a specific region of the protective layer by controlling regions of the protective layer that are exposed to the acidic etching solution. The thin metal wires can be removed in such a manner that a specific region of the conductive layer, which is located under the protective layer, is exposed to the acidic etching solution through cavities formed in the specific region of the protective layer by removing the particles. In accordance with the base material with the transparent conductive film according to the first aspect, the conductive layer can be patterned by photolithography similarly to the patterning of an ITO film in spite of that the protective layer is placed on the conductive layer. Thus, the conductive layer can be readily and precisely patterned. Incidentally, a high-definition pattern can be formed by photolithography.

In accordance with the base material with the transparent conductive film according to the first aspect, the resin contained in the protective layer can be left therein even after the patterning of the protective layer. Therefore, the protective layer can sufficiently protect the conductive layer. Thus, it is prevented that the conductive layer is exposed and therefore the durability of the thin metal wire is reduced. Since the resin contained in the protective layer remains even after the patterning of the protective layer, it is prevented that the thickness of a non-conductive portion is more significantly reduced than the thickness of a conductive portion even if, in the non-conductive portion, the particles in the protective layer and the thin metal wires in the conductive layer are removed by etching. Thus, in accordance with the base material with the transparent conductive film according to the first aspect, the difference in level between the conductive portion and the non-conductive portion can be reduced. Hence, a pattern can be obscured. The base material with the transparent conductive film according to the first aspect need not be laminated to another base material in the case of patterning the conductive layer. Thus, there is no problem, such as pasting precision or dust catching, relating to yield.

A second aspect of the present disclosure provides a base material with a transparent conductive film in which the metal wires are silver nanowires in the first aspect.

In accordance with the base material with the transparent conductive film according to the second aspect, a conductive layer having higher transparency and higher conductivity can be obtained as compared to the case of using other thin metal wires.

A third aspect of the present disclosure provides a base material with a transparent conductive film in which the metal wires are soluble in the acidic etching solution in the first or second aspect.

In accordance with the base material with the transparent conductive film according to the third aspect, the thin metal wires in the conductive layer can be etched using the same etching solution as that used to etch the particles in the protective layer. Therefore, an etching solution need not be changed between the etching of the particles in the protective layer and the etching of the thin metal wire in the conductive layer. That is, the thin metal wire in the conductive layer can be etched subsequently to the etching of the particles in the protective layer. Thus, In accordance with the base material with the transparent conductive film according to the third aspect, the conductive layer can be patterned by a simpler process.

A fourth aspect of the present disclosure provides a base material with a transparent conductive film in which the particle includes at least one selected from the group consisting of SnO₂, ZnO, ITO, IZO, ATO, and In₂O₃ in any one of the first to third aspects.

In accordance with the base material with the transparent conductive film according to the fourth aspect, the surface resistance can be reduced with the transparency maintained. Furthermore, a pattern can be obscured in such a manner that the refractive index is adjusted by selecting particles.

A fifth aspect of the present disclosure provides a method for manufacturing a base material with a transparent conductive film including a conductive portion and a non-conductive portion. The method includes (a) preparing the base material with the transparent conductive film on or above the base material, the transparent conductive film including: a conductive layer containing metal wires; and a protective layer being located on a side of the conductive layer and containing a resin and a particle, the side not opposing to the base material, the particle being soluble in an acidic etching solution, the resin being resistant to the acidic etching solution; (b) providing a mask having a pattern corresponding to the conductive portion on the protective layer; (c) exposing the protective layer to an acidic etching solution through the mask; and (d) removing the mask.

In accordance with the manufacturing method according to the fifth aspect, the particles contained in the protective layer are removed by etching. Therefore, photolithography can be used to pattern the conductive layer in spite of that the protective layer is placed on the conductive layer. This enables the conductive layer to be readily and precisely patterned in accordance with the manufacturing method according to the fifth aspect. Incidentally, since photolithography can be used, a high-definition pattern.

A sixth aspect of the present disclosure provides a touch panel including a transparent conductive pattern-including base material obtained by patterning the conductive layer of the transparent conductive film-including base material according to any one of the first to fourth aspects into a conductive portion and a non-conductive portion.

The base material with the transparent conductive film included in the touch panel according to the sixth aspect is formed using the base material with the transparent conductive film according to any one of the first to fourth aspects. That is, the base material with the transparent conductive film is one obtained by readily and precisely patterning the conductive layer of the base material with the transparent conductive film. Thus, in accordance with the touch panel according to the sixth aspect, a high-reliability touch panel can be provided at low cost.

A seventh aspect of the present disclosure provides a solar cell including a base material with a transparent conductive film obtained by patterning the conductive layer of the base material with the transparent conductive film according to any one of the first to fourth aspects into a conductive portion and a non-conductive portion.

The base material with the transparent conductive film included in the solar cell according to the seventh aspect is formed using the base material with the transparent conductive film according to any one of the first to fourth aspects. That is, the base material with the transparent conductive film is one obtained by readily and precisely patterning the conductive layer of the base material with the transparent conductive film. Thus, in accordance with the solar cell according to the seventh aspect, a high-reliability can be provided at low cost.

An eighth aspect of the present disclosure provides a base material with a transparent conductive film on or above the base material. The transparent conductive film includes a conductive layer, and a protective layer being located on a side of the conductive layer and containing a resin, the side not opposing to the base material. The transparent conductive film includes a conductive portion and a non-conductive portion in an in-plane direction. The conductive layer contains no metal wires in the conductive portion or contains less metal wires per unit area in the non-conductive portion than the conductive layer contains the metal wires per unit area in the conductive portion. The protective layer contains a particle in the conductive portion, and includes an aperture penetrating the resin in a thickness direction in the non-conductive portion. The particle is soluble in an acidic etching solution, and the resin is resistant to the acidic etching solution.

A ninth aspect of the present disclosure provides a touch panel including the base material with the transparent conductive film according to the eighth aspect. Thus, in accordance with the touch panel according to the ninth aspect, a high-reliability touch panel can be provided at low cost.

A tenth aspect of the present disclosure provides a solar cell including the base material with the transparent conductive film according to the eighth aspect. Thus, in accordance with the solar cell according to the tenth aspect, a high-reliability solar cell can be provided at low cost.

Embodiments of the present disclosure are described below in detail.

### First Embodiment

### Configuration of Base Material with the Transparent Conductive Film

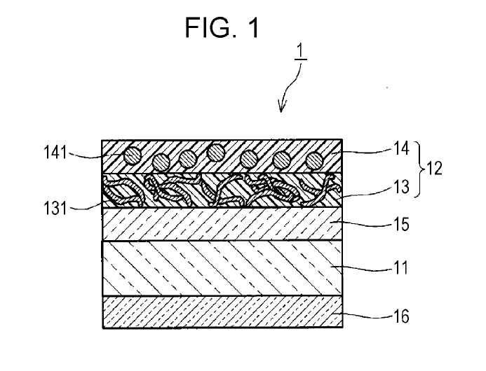

FIG. 1 is a sectional view of a base material with the transparent conductive film 1 according to an embodiment of the present disclosure. The base material with the transparent conductive film 1 includes a base material 11 and a transparent conductive film 12. The transparent conductive film 12 includes a conductive layer 13 placed on the base material 11 side and a protective layer 14 covering the conductive layer 13. The base material with the transparent conductive film 1 may further include an intermediate layer 15 placed between the transparent conductive film 12 and the base material 11 as shown in FIG. 1. This is not particularly limited. The base material with the transparent conductive film 1 may further include a coated layer 16 placed on a surface of the base material 11 that is opposite to a surface of the base material 11 that has the transparent conductive film 12 thereon.

### Base Material

The base material 11 may be light-transmissive. The base material 11 may have a light transmittance of 50% or more, more desirably 70% or more, and further more desirably 80% or more.

The shape of the base material 11 is not particularly limited and the base material 11 may be plate-shaped or film-shaped. In particular, the base material 11 may be film-shaped from the viewpoint of enhancing the productivity and transportability of the base material 11.

When the base material 11 is film-shaped, the thickness of the base material 11 may range from 10 μm to 500 μm. In this case, the transparency of the base material 11 is particularly good and the operability thereof is also good during production and handling. The thickness of the base material 11 may range from 25 μm to 200 μm. In particular, when the thickness of the base material 11 ranges from 25 μm to 150 μm, thickness reduction and weight reduction are possible and the occurrence of interference on the front and back of the base material with the transparent conductive film 1 is suppressed. Furthermore, when the thickness of the base material 11 is within this range, the thermal shrinkage of the base material 11 is suppressed when being heated. Thus, failures such as the deterioration in workability of the base material 11 due to thermal shrinkage are suppressed.

A material for forming the base material 11 is not particularly limited. Examples of the material for forming the base material 11 include glass, transparent resins. Examples of the transparent resins include polyethylene terephthalate, polybutylene terephthalate, polycarbonate, polymethyl methacrylate copolymers, triacetylcellulose, polyolefins, polyamides, polyvinyl chloride, amorphous polyolefins, cycloolefin polymers, cycloolefin copolymers. In particular, the base material 11 may be made of polyester. Among polyester films, a biaxially stretched film made of polyethylene terephthalate (PET) or polyethylene naphthalate has particularly excellent mechanical properties, heat resistance, chemical resistance, and the like.

The polyester used to form the base material 11 may be an aromatic polyester produced by the reaction of an aromatic dicarboxylic acid such as terephthalic acid, isophthalic acid, 2,6-naphthalenedicarboxylic acid, or 4,4′-diphenyldicarboxylic acid with a glycol such as ethylene glycol, 1,4-butanediol, 1,4-cyclohexanedimethanol, or 1,6-hexanediol. In particular, the polyester used to form the base material 11 may be polyethylene terephthalate and polyethylene 2,6-naphthalenedicarboxylate. The polyester may be one produced by copolymerizing the above-exemplified compounds.

The base material 11 may contain organic or inorganic particles. In this case, the base material 11 has enhanced windability, transportability, and the like. Examples of particles that may be contained in the base material 11 include calcium carbonate particles, calcium oxide particles, aluminium oxide particles, kaolin particles, silicon dioxide particles, zinc oxide particles, cross-linked acrylic resin particles, cross-linked polystyrene particles, urea resin particles, melamine resin particles, cross-linked silicone resin particles.

The base material 11 may further contain a colorant, an antistatic agent, an ultraviolet absorber, an antioxidant, a lubricant, a catalyst, another resin, and the like unless the transparency of the base material 11 is impaired.

The base material 11 may have a haze of 3% or less. In this case, the visibility of an image passing through the transparent conductive film-including base material 1 is high and therefore the base material 11 is suitable particularly for members for optical use. The haze of the base material 11 may be 1.5% or less.

### Coated Layer

The coated layer 16 may be transparent and may be placed on the surface of the base material 11 that is opposite to the surface of the base material 11 that has the transparent conductive film 12 thereon. In this case, a low-molecular weight component is unlikely to precipitate from the base material 11 and therefore the whitening of the base material 11 is suppressed. Hence, the transparency of the transparent conductive film-including base material 1 is maintained well.

A material for forming the coated layer 16 is not particularly limited. The coated layer 16 is made of, for example, an acrylate resin, a urethane acrylate resin.

In order that the coated layer 16 sufficiently suppresses the precipitation of the low-molecular weight component from the base material 11, the thickness of the coated layer 16 may range from 0.5 μm to 10 μm.

The coated layer 16 may have anti-blocking properties. That is, when the base material with a transparent conductive film 1 is rolled and is stacked, blocking may be suppressed by the coated layer 16. Therefore, the coated layer 16 may have surface irregularities. The coated layer 16 may be surface-machined so as to have the surface irregularities. Alternatively, the coated layer 16 may contain filler such as silica particles or acrylic particles to have the surface irregularities. In this case, the coated layer 16 may contain, for example, 80% to 95% by mass of silica particles or acrylic particles and may further contain 5% to 20% by mass of particles with an average size of 100 nm to 300 nm.

The base material with a transparent conductive film 1 may have increased slippability due to the coated layer 16. Therefore, the coated layer 16 may contain, for example, a silicone-based leveling agent.

In the case of forming the coated layer 16, a surface of the base material 11 that is to be in contact with the coated layer 16 may be treated before the coated layer 16 is formed. In this case, the wettability, adhesion, and/or the like between the base material 11 and the coated layer 16 can be enhanced. A surface of the base material 11 that is to be in contact with the intermediate layer 15 may be treated before the intermediate layer 15 is formed. In this case, the wettability, adhesion, and/or the like between the base material 11 and the intermediate layer 15 can be enhanced. Examples of a method for surface-treating the base material 11 include physical surface treatment including plasma treatment, corona discharge treatment, and flame treatment and chemical surface treatment using a coupling agent, an acidic component, an alkaline component, or the like.

### Intermediate Layer

The intermediate layer 15 is described below. The intermediate layer 15 may have the effect of increasing the adhesion between the base material 11 and the transparent conductive film 12 (the conductive layer 13 in an example shown in FIG. 1), the effect of suppressing the precipitation of the low-molecular weight component from the base material 11, and the effect of optical adjustment for reducing the visibility of a conductive pattern obtained by patterning the conductive layer 13. The intermediate layer 15 may have a thickness of 300 nm or less and may have a thickness of 50 nm to 200 nm. The refractive index of the intermediate layer 15 may be greater than the refractive index of the coated layer 16 and may be 1.60 or more in particular.

Since the refractive index and thickness of the intermediate layer 15 is adjusted as described above, the color texture and etching pattern of the conductive layer 13 are unlikely to appear on the appearance of the base material with a transparent conductive film 1.

The intermediate layer 15 may be formed from a curable reactive resin composition, for example, at least one of a thermosetting resin composition and an ionizing radiation-curable resin composition.

The thermosetting resin composition contains a thermosetting resin such as a phenol resin, a urea resin, a diallyl phthalate resin, a melamine resin, an unsaturated polyester resin, a polyurethane resin, an epoxy resin, an aminoalkyd resin, a silicone resin, or a polysiloxane resin. The thermosetting resin composition may further contain a cross-linking agent, a polymerization initiator, a curing agent, a curing accelerator, a solvent in addition to the thermosetting resin as required. The intermediate layer 15 can be formed in such a manner that the thermosetting resin composition is applied to, for example, the base material 11 and is then thermally cured by heating the thermosetting resin composition.

The ionizing radiation-curable resin composition may contain a functional acrylate group-containing resin. Examples of the functional acrylate group-containing resin include oligomers and prepolymers of a (meth)acrylate of a polyfunctional compound with a relatively low molecular weight. Examples of the polyfunctional compound include polyester resins, polyether resins, acrylic resins, epoxy resins, urethane resins, alkyd resins, spiroacetal resins, polybutadiene resins, polythiolpolyene resins, polyvalent alcohols. The ionizing radiation-curable resin composition may further contain a reactive diluent. Examples of the reactive diluent include monofunctional monomers such as ethyl (meth)acrylate, ethylhexyl (meth)acrylate, styrene, methylstyrene, and N-vinylpyrrolidone; polyfunctional monomers such as trimethylolpropane tri(meth)acrylate, hexanediol di(meth)acrylate, tripropylene glycol di(meth)acrylate, diethylene glycol di(meth)acrylate, pentaerythritol tri(meth)acrylate, dipentaerythritol hexa(meth)acrylate, 1,6-hexanediol di(meth)acrylate, and neopentyl glycol di(meth)acrylate.

When the ionizing radiation-curable resin composition is a photocurable resin composition such as an ultraviolet-curable resin composition, the photocurable resin composition may contain a photopolymerization initiator. Examples of the photopolymerization initiator include acetophenones, benzophenones, α-amyloxime esters, thioxanthones. The photocurable resin may contain a photosensitizer in addition to or instead of the photopolymerization initiator. Examples of the photosensitizer include n-butylamine, triethylamine, tri-n-butylphosphine, thioxanthone. The intermediate layer 15 can be formed in such a manner that the photocurable resin composition is applied to, for example, the base material 11 and is then photocured by irradiating the photocurable resin composition with light including ultraviolet rays.

The refractive index of the intermediate layer 15 can be readily adjusted by adjusting the composition of a resin composition for forming the intermediate layer 15. When the intermediate layer 15 contains particles for refractive index adjustment, the refractive index of the intermediate layer 15 may be adjusted by adjusting the content of the particles.

The particles for refractive index adjustment may have a sufficiently small size, that is, the particles for refractive index adjustment may be so-called ultrafine particles. In this case, the light transmittance of the intermediate layer 15 is sufficiently maintained. In particular, the size of the particles for refractive index adjustment may range from 0.5 nm to 150 nm. The size of the particles for refractive index adjustment corresponds to the diameter of a circle (area-equivalent circle) having the same area as the projected area calculated from an electron micrograph of the particles.

The particles for refractive index adjustment may have relatively high refractive index and may have a refractive index of 1.6 or more in particular. The particles for refractive index adjustment may be particles of a metal oxide. Examples of a material for forming the particles for refractive index adjustment include TiO₂ (a refractive index of 2.3 to 2.7), CeO₂ (a refractive index of 1.95), Y₂O₃ (a refractive index of 1.87), La₂O₃ (a refractive index of 1.95), ZrO₂ (a refractive index of 2.05), Al₂O₃ (a refractive index of 1.63).

The intermediate layer 15 may contain particles containing one or more oxides and may also contain at least one of a functional methacrylic silane and a functional acrylic silane. This increases the adhesion between the intermediate layer 15 and the conductive layer 13. Examples of the functional methacrylic silane include 3-methacryloxypropyltrimethoxysilane, 3-methacryloxypropylmethyldimethoxysilane. Examples of the functional acrylic silane include 3-acryloxypropyltrimethoxysilane, 3-acryloxypropylmethyldimethoxysilane.

The contents of the functional methacrylic and acrylic silanes in the intermediate layer 15 are not particularly limited. The sum of the contents of the functional methacrylic and acrylic silanes in the intermediate layer 15 may range from 5% to 30% by mass. When the sum of the contents thereof is 5% by mass or more, the adhesion between the intermediate layer 15 and the conductive layer 13 is sufficiently high. When the sum of the contents thereof is 30% by mass or less, the cross-link density of the intermediate layer 15 is sufficiently increased and the hardness of the intermediate layer 15 is sufficiently increased.

Before the transparent conductive film 12 (the conductive layer 13 in the example shown in FIG. 1) is formed, a surface of the intermediate layer 15 that is opposite to a surface of the intermediate layer 15 that has the base material 11 thereon may be treated. In this case, the wettability, adhesion, and/or the like between the intermediate layer 15 and the conductive layer 13 can be enhanced. Examples of a method for surface-treating the intermediate layer 15 include physical surface treatment including plasma treatment, corona discharge treatment, and flame treatment; chemical surface treatment using a coupling agent.

The intermediate layer 15 is not limited to the above. In the case of applying the intermediate layer 15 to a silicon solar cell below, the intermediate layer 15 may be a stack of layers, such as a counter electrode, an n-type semiconductor layer, and a p-type semiconductor layer, forming a solar cell.

### Conductive Layer

The conductive layer 13 is described below. The conductive layer 13 contains thin metal wires 131 and is transparent. Herein, a material used to form the thin metal wires 131 may be an arbitrary metallic conductive material. Examples of the thin metal wires 131 include fibers and nanowires made from metals such as gold, platinum, silver, nickel, silicon, copper, aluminum, zirconium, hafnium, vanadium, niobium, tantalum, chromium, molybdenum, manganese, technetium, rhenium, iron, osmium, cobalt, zinc, scandium, boron, gallium, indium, germanium, tin, and magnesium and alloys of these metals. In particular, metal nanowires can achieve low resistance and high transmittance. A means for manufacturing a metal nanowire is not particularly limited and, for example, a known means such as a liquid-phase method or a vapor-phase method can be used to manufacture the metal nanowire. A particular method for manufacturing the metal nanowire is not particularly limited and a known manufacturing method can be used to manufacture the metal nanowire. For example, the following methods can be cited as a method for manufacturing a silver (Ag) nanowire: manufacturing methods described in Adv. Mater. 2002, 14, pp. 833-837; Chem. Mater. 2002, 14, pp. 4736-4745; Japanese Unexamined Patent Application Publication (Translation of PCT Application) No. 2009-505358. A method described in Japanese Unexamined Patent Application Publication No. 2006-233252 can be cited as a method for manufacturing a gold (Au) nanowire. A method described in Japanese Unexamined Patent Application Publication No. 2002-266007 can be cited as a method for manufacturing a copper (Cu) nanowire. A method described in Japanese Unexamined Patent Application Publication No. 2004-149871 can be cited as a method for manufacturing a cobalt (Co) nanowire. In particular, the manufacturing methods described in Adv. Mater. 2002, 14, pp. 833-837 and Chem. Mater. 2002, 14, pp. 4736-4745 can be used to readily manufacture the Ag nanowire in an aqueous system in a large amount. Silver has the highest volume resistivity among metals and therefore can be used to manufacture metal nanowires used this embodiment. The metal nanowires may be Ag nanowires. This allows the conductive layer 13 to have higher transparency and conductivity as compared to the case of using other metal nanowires.

The thin metal wires 131 may have an average diameter of 100 nm or less from the viewpoint of transparency and may have an average diameter of 10 nm or more from the viewpoint of conductivity. When the average diameter of the thin metal wires 131 is 100 nm or less, the reduction in light transmittance of the thin metal wires 131 can be suppressed. When the average diameter of the thin metal wires 131 is 10 nm or more, the thin metal wires 131 are allowed to function as conductors. The larger the average diameter of the thin metal wires 131 is, the higher the conductivity of the thin metal wires 131 is. Therefore, the average diameter of the thin metal wires 131 may be 20 nm to 100 nm and may be 40 nm to 100 nm. The thin metal wires 131 may have an average length of 1 μm or more from the viewpoint of conductivity and may have an average length of 100 μm or less from the viewpoint of the influence of aggregation on transparency. Thus, the average length of the thin metal wires 131 may be 1 μm to 50 μm and may be 3 μm to 50 μm. The average diameter and average length of the thin metal wires 131 can be determined in such a manner that a sufficient number of the thin metal wires 131 are photographed by electron microphotography using a scanning electron microscope (SEM) or a transmission electron microscope (TEM) and measurements of images of the individual thin metal wires 131 are arithmetically averaged. The thin metal wires 131 should be primarily measured for length in such a state that the thin metal wires 131 are linearly expanded. However, the thin metal wires 131 are actually folded in many cases. Thus, the length of each thin metal wire 131 is determined in such a manner that the projected diameter and projected area of the thin metal wire 131 are calculated from an electron micrograph of the thin metal wire 131 using an image analyzer and a cylinder is assumed (length=projected area/projected diameter). The number of the measured thin metal wires 131 may be at least 100 and may be three hundred or more.

The conductive layer 13 is formed from, for example, a first composition containing the thin metal wires 131 and a first resin component. In this case, the conductive layer 13 can be formed by a wet film-forming method.

Examples of the first resin component, which is contained in the first composition, include silicone resins, fluororesins, acrylic resins, polyethylene resins, polypropylene resins, polyethylene terephthalate resins, polymethyl methacrylate resins, polystyrene resins, polyethersulfone resins, polyarylate resins, polycarbonate resins, polyurethane resins, polyacrylonitrile resins, polyvinyl acetal resins, polyamide resins, polyimide resins, diallyl phthalate resins, polyvinyl chloride resins, polyvinylidene chloride resins, polyvinyl acetate resins, other thermoplastic resins, copolymers produced by polymerizing two or more types of monomers used to produce these resins.

The first resin component may contain a curable reactive resin. The curable reactive resin may be, for example, at least one of a thermosetting resin and an ionizing radiation-curable resin.

Examples of the thermosetting resin include phenol resins, urea resins, diallyl phthalate resins, melamine resins, unsaturated polyester resins, polyurethane resins, epoxy resins, aminoalkyd resins, silicone resins, polysiloxane resins. The first composition may further contain a cross-linking agent, a polymerization initiator, a curing agent, a curing accelerator, a solvent, and/or the like in addition to the thermosetting resin as required.

The ionizing radiation-curable resin may be a functional acrylate group-containing resin. Examples of the functional acrylate group-containing resin include oligomers and prepolymers of a (meth)acrylate of a polyfunctional compound with a relatively low molecular weight. Examples of the polyfunctional compound include polyester resins, polyether resins, acrylic resins, epoxy resins, urethane resins, alkyd resins, spiroacetal resins, polybutadiene resins, polythiolpolyene resins, polyvalent alcohols. When the first composition contains the ionizing radiation-curable resin, the first composition may further contain a reactive diluent. Examples of the reactive diluent include monofunctional monomers such as ethyl (meth)acrylate, ethylhexyl (meth)acrylate, styrene, methylstyrene, and N-vinylpyrrolidone and polyfunctional monomers such as trimethylolpropane tri(meth)acrylate, hexanediol di(meth)acrylate, tripropylene glycol di(meth)acrylate, diethylene glycol di(meth)acrylate, pentaerythritol tri(meth)acrylate, dipentaerythritol hexa(meth)acrylate, 1,6-hexanediol di(meth)acrylate, and neopentyl glycol di(meth)acrylate.

When the ionizing radiation-curable resin is a photocurable resin such as an ultraviolet-curable resin, the first composition may further contain a photopolymerization initiator. Examples of the photopolymerization initiator include acetophenones, benzophenones, α-amyloxime esters, thioxanthones. When the first composition contains the photocurable resin, the first composition may contain a photosensitizer in addition to or instead of the photopolymerization initiator. Examples of the photosensitizer include n-butylamine, triethylamine, tri-n-butylphosphine, thioxanthone.

The first composition may contain a solvent as required. The solvent used is, for example, an organic solvent, water, or a combination of the organic solvent and water. Examples of the organic solvent include alcohols such as methanol, ethanol, and isopropyl alcohol (IPA); ketones such as methyl ethyl ketone, methyl isobutyl ketone, and cyclohexanone; esters such as ethyl acetate and butyl acetate; halogenated hydrocarbons; aromatic hydrocarbons such as toluene and xylene; and mixtures of these compounds.

The content of the solvent in the first composition is appropriately adjusted such that solid matter can be uniformly dissolved or dispersed in the first composition. The concentration of the solid matter in the first composition may range from 0.1% to 50% by mass and may range 0.5% to 30% by mass.

The first composition is applied to the intermediate layer 15 and is then formed into a film, whereby the conductive layer 13 is obtained. For example, an appropriate method such as a roll coating method, a spin coating method, or a dip coating method is used to apply the first composition. A technique for forming the first composition into a film is appropriately selected depending on the type of the first resin component, which is contained in the first composition. When the first composition contains, for example, the thermosetting resin, the first composition is heated and is thereby cured, whereby the conductive layer 13 is formed so as to contain the thin metal wires 131. When the first composition contains the ionizing radiation-curable resin, the first composition is irradiated with ionizing radiation including ultraviolet rays and is thereby cured, whereby the conductive layer 13 is formed so as to contain the thin metal wires 131.

The refractive index of the conductive layer 13 is not particularly limited and may range from 1.35 to 1.65 in order that the white color of the conductive layer 13 is sufficiently inconspicuous in view of the appearance of the base material with a transparent conductive film 1. The thickness of the conductive layer 13 is not particularly limited and may range from 10 nm to 300 nm. The refractive index of the conductive layer 13 can be readily adjusted by varying the composition of the first composition.

### Protective Layer

The protective layer 14 is described below. The protective layer 14 covers the conductive layer 13, is transparent, reduces the deterioration in conductivity of the conductive layer 13, and protects the conductive layer 13 from damage including flaws. The protective layer 14 contains a second resin component and particles 141 soluble in acidic etching solutions. In the protective layer 14, the particles 141 are dispersed in resin.

The particles 141, which are soluble in acidic etching solutions, may include at least one selected from the group consisting of SnO₂, ZnO, ITO, IZO, ATO, and In₂O₃. The shape of the particles 141 is not particularly limited. The particles 141 may be solid, hollow, or porous.

The particles 141 may have a sufficiently small size, that is, the particles 141 may be so-called ultra-fine particles. In this case, the light transmittance of the protective layer 14 is sufficiently maintained. The size of the particles 141 may range from 0.5 nm to 150 nm in particular. The size of the particles 141 corresponds to the diameter of a circle (area-equivalent circle) having the same area as the projected area calculated from an electron micrograph of the particles 141.

The content of the particles 141 in the protective layer 14 is not particularly limited. The content of the particles 141 in the protective layer 14 may range from 0.1% to 60% by mass and may range 1% to 40% by mass. When the content of the particles 141 in the protective layer 14 is more than 60% by mass, the effect of protecting the conductive layer 13 is reduced in some cases. However, when the content of the particles 141 in the protective layer 14 is less than 0.1% by mass, cavities sufficient to allow an etching solution for etching the thin metal wires 131, which are contained in the conductive layer 13 located under the protective layer 14, to reach the conductive layer 13 are not formed and therefore the effect of sufficiently etching the thin metal wires 131 is not obtained in some cases.

The protective layer 14 is formed from, for example, a second composition containing the particles 141 and the second resin component. In this case, the protective layer 14 can be formed by a wet film-forming method.

The second resin component, which is contained in the second composition, is not particularly limited and may be resin resistant to an acidic etching solution used to etch the particles 141. Substantially the same resin as the resin component of the conductive layer 13 can be used. The term “resin resistant to an acidic etching solution” as used herein refer to resin that is substantially insoluble in the acidic etching solution, that is, resin that is not substantially altered by an etching process using the acidic etching solution. Examples of the second resin component include silicone resins, fluororesins, acrylic resins, polyethylene resins, polypropylene resins, polyethylene terephthalate resins, polymethyl methacrylate resins, polystyrene resins, polyethersulfone resins, polyarylate resins, polycarbonate resins, polyurethane resins, polyacrylonitrile resins, polyvinyl acetal resins, polyamide resins, polyimide resins, diallyl terephthalate resins, polyvinyl chloride resins, polyvinylidene chloride resins, polyvinyl acetate resins, other thermoplastic resins, copolymers produced by polymerizing two or more types of monomers used to produce these resins.

The second resin component may contain a curable reactive resin. The curable reactive resin may be, for example, at least one of a thermosetting resin and an ionizing radiation-curable resin.

Examples of the thermosetting resin include phenol resins, urea resins, diallyl phthalate resins, melamine resins, unsaturated polyester resins, polyurethane resins, epoxy resins, aminoalkyd resins, silicone resins, polysiloxane resins. The second composition may further contain a cross-linking agent, a polymerization initiator, a curing agent, a curing accelerator, a solvent, and/or the like in addition to the thermosetting resin as required.

The ionizing radiation-curable resin may be a functional acrylate group-containing resin. Examples of the functional acrylate group-containing resin include oligomers and prepolymers of a (meth)acrylate of a polyfunctional compound with a relatively low molecular weight. Examples of the polyfunctional compound include polyester resins, polyether resins, acrylic resins, epoxy resins, urethane resins, alkyd resins, spiroacetal resins, polybutadiene resins, polythiolpolyene resins, polyvalent alcohols. When the second composition contains the ionizing radiation-curable resin, the second composition may further contain a reactive diluent. Examples of the reactive diluent include monofunctional monomers such as ethyl (meth)acrylate, ethylhexyl (meth)acrylate, styrene, methylstyrene, and N-vinylpyrrolidone and polyfunctional monomers such as trimethylolpropane tri(meth)acrylate, hexanediol di(meth)acrylate, tripropylene glycol di(meth)acrylate, diethylene glycol di(meth)acrylate, pentaerythritol tri(meth)acrylate, dipentaerythritol hexa(meth)acrylate, 1,6-hexanediol di(meth)acrylate, and neopentyl glycol di(meth)acrylate.

When the ionizing radiation-curable resin is a photocurable resin such as an ultraviolet-curable resin, the second composition may further contain a photopolymerization initiator. Examples of the photopolymerization initiator include acetophenones, benzophenones, α-amyloxime esters, thioxanthones. When the first composition contains the photocurable resin, the first composition may contain a photosensitizer in addition to or instead of the photopolymerization initiator. Examples of the photosensitizer include n-butylamine, triethylamine, tri-n-butylphosphine, thioxanthone.

The second composition may contain a solvent as required. The solvent used is, for example, an organic solvent, water, or a combination of the organic solvent and water. Examples of the organic solvent include alcohols such as methanol, ethanol, and isopropyl alcohol (IPA); ketones such as methyl ethyl ketone, methyl isobutyl ketone, and cyclohexanone; esters such as ethyl acetate and butyl acetate; halogenated hydrocarbons; aromatic hydrocarbons such as toluene and xylene; and mixtures of these compounds.

The content of the solvent in the second composition is appropriately adjusted such that solid matter can be uniformly dissolved or dispersed in the second composition. The concentration of the solid matter in the second composition may range from 0.1% to 50% by mass and may range 0.5% to 30% by mass.

The second composition is applied to the conductive layer 13 and is then formed into a film, whereby the protective layer 14 is obtained. For example, an appropriate method such as a roll coating method, a spin coating method, or a dip coating method is used to apply the second composition. A technique for forming the second composition into a film is appropriately selected depending on the type of the second resin component, which is contained in the second composition. When the second composition contains, for example, the thermosetting resin, the second composition is heated and is thereby cured, whereby the protective layer 14 is formed so as to contain the particles 141. When the second composition contains the ionizing radiation-curable resin, the second composition is irradiated with ionizing radiation including ultraviolet rays and is thereby cured, whereby the protective layer 14 is formed so as to contain the particles 141.

The refractive index of the protective layer 14 is not particularly limited and may be 1.60 or less in order that the white color of the transparent conductive film-including base material 1 is sufficiently inconspicuous in view of appearance. The thickness of the protective layer 14 is not particularly limited and may range from 10 nm to 200 nm.

The acidic etching solution, in which the particles 141 are soluble, is not particularly limited and is appropriately selected from the group consisting of, for example, aqua regia (a mixture of hydrochloric acid (HCl) and nitric acid (HNO₃)), a hydrochloric acid solution of iron(III) chloride (FeCl₃ in HCl), phosphoric acid (H₃PO₄), and hydrobromic acid (HBr).

Method for Manufacturing Base Material with a Transparent Conductive Film

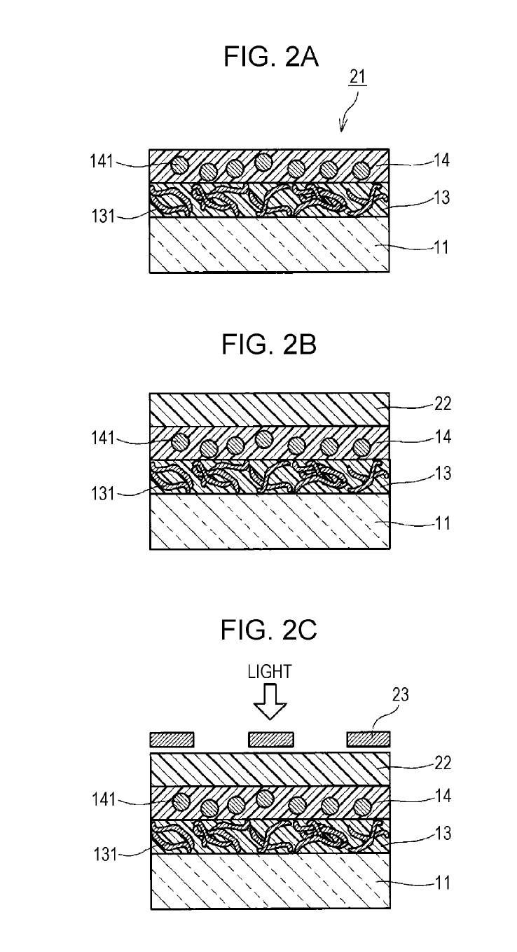

A method for manufacturing a base material with a transparent conductive film including a conductive portion and a non-conductive portion according to an embodiment of the present disclosure is described below with reference to FIGS. 2A to 2F. The manufacturing method includes (a) preparing a base material with a transparent conductive film 21 comprising a base material 11; and a transparent conductive film 12 on or above the base material 11, the transparent conductive film 12 including: a conductive layer 13 containing thin metal wires 131; and a protective layer 14 being located on the conductive layer 13 and containing a resin and a particles 141 as shown in FIG. 2A, (b) providing a resist mask 24 having a pattern corresponding to the conductive portion 25 on the protective layer 14 as shown in FIGS. 2B to 2D, (c) exposing the protective layer 14 to an acidic etching solution through the resist mask as shown in FIG. 2E, and (d) removing the resist mask 24 as shown in FIG. 2F. In Step (C), the particles 141 are dissolved in the acidic etching solution, whereby cavities are formed in the protective layer 14.

In Step (a), the base material with a transparent conductive film 21 is prepared. The base material with a transparent conductive film 21 shown in FIG. 2A is different from the base material with a transparent conductive film 1 shown in FIG. 1 in that the base material with a transparent conductive film 21 includes no intermediate layer 15 or coated layer 16. However, the configuration of the base material 11, the conductive layer 13, and the protective layer 14 of the base material with a transparent conductive film 21 and methods for preparing these members are the same as the configuration of those of the base material with a transparent conductive film 1 and methods for preparing those of the base material with a transparent conductive film 1. In Step (a), the base material with a transparent conductive film 1 can be prepared as described in the first embodiment.

In Step (b), a resist film 22 is formed on the protective layer 14 of the base material with a transparent conductive film 21 as shown in FIG. 2B. Next, the resist film 22 is exposed to UV light through a mask 23 as shown in FIG. 2C, whereby the resist mask 24 is formed so as to have a desired pattern as shown in FIG. 2D. The resist mask 24 corresponds to the pattern having the conductive portions 25 and non-conductive portions 26 formed in the conductive layer 13.

In Step (c), regions of the protective layer 14 that are not covered by the resist mask 24 are exposed to the acidic etching solution. Herein, the case where the acidic etching solution dissolves the thin metal wires 131 in the conductive layer 13 is described. In the regions of the protective layer 14 that are not covered by the resist mask 24, the particles 141 in the protective layer 14 are dissolved in the acidic etching solution, whereby cavities are formed. The acidic etching solution enters the cavities to reach the conductive layer 13 and dissolves the thin metal wires 131 in the conductive layer 13. In other words, the acidic etching solution dissolves the particle 141 in the protective layer 14, whereby cavities are formed. The cavities form apertures that penetrate the protective layer 14. The acidic etching solution reaches the conductive layer 13 through the apertures and dissolves the thin metal wires 131 in the conductive layer 13. In this way, the non-conductive portions 26 are formed as shown in FIG. 2E. In regions of the protective layer 14 that are covered by the resist mask 24, the conductive layer 13 and the protective layer 14 covering the conductive layer 13 remains and therefore the conductive portions 25 are formed.

Incidentally, an etching solution different from the etching solution used to etch the thin metal wires 131 in the conductive layer 13 may be used to etch the particles 141 in the protective layer 14.

The acidic etching solution used can be appropriately selected from the group consisting of aqua regia (a mixture of HCl and HNO₃), a hydrochloric acid solution of iron(III) chloride (FeCl₃ in HCl), phosphoric acid (H₃PO₄), and hydrobromic acid (HBr) as described above. In particular, when the particles 141 are metal oxide particles, it is difficult to etch the particles 141 and therefore an acid mixture such as aqua regia (a mixture of HCl and HNO₃) may be used.

Finally, in Step (d), the resist mask 24 is removed from the protective layer 14, whereby a desired pattern having the conductive portions 25 and the non-conductive portions 26 is formed as shown in FIG. 2F.

In accordance with the manufacturing method according to this embodiment, a conductive pattern having the conductive portions 25 and the non-conductive portions 26 can be readily and precisely formed in the conductive layer 13 by wet etching treatment in such a state that the conductive layer 13 is covered by the protective layer 14. This enables the base material with a transparent conductive film including a conductive portion and a non-conductive portion to be manufactured. The base material with a transparent conductive film including a conductive portion and a non-conductive portion can be used as an electrode for electronic devices.

FIG. 2F shows the base material with a transparent conductive film including a conductive portion and a non-conductive portion. The transparent conductive film includes a conductive layer 13 and a protective layer 14 being located on the conductive layer 14 and containing a resin. The base material with a transparent conductive film includes the conductive portions 25 and the non-conductive portions 26 in an in-plane direction. In the base material with a transparent conductive film, the conductive layer 13 includes portions which correspond to the conductive portions 25 and which contain the thin metal wires 131. And the conductive layer 13 also includes portions which correspond to the non-conductive portions 26 and which contain no thin metal wires 131 or contain a smaller number of the thin metal wires 131 as compared to the portions corresponding to the conductive portions 25. That is, the number of the thin metal wires 131 per unit area of the non-conductive portions 26 is less than the number of the thin metal wires 131 per unit area of the conductive portions 25. Therefore, in the non-conductive portions 26, the conductive layer 13 exhibits insulating properties. The protective layer 14 includes portions which correspond to the conductive portions 25 and which contain the resin and the particles 141. And the protective layer 14 also includes portions which correspond to the non-conductive portions 26 and which contain the resin and apertures penetrating the resin in a thickness direction. The term “apertures penetrating the resin” as used herein includes apertures filled with a material other than the resin that constitutes the protective layer 14. That is, when the protective layer 14 has apertures penetrating the resin in the thickness direction, the apertures correspond to “apertures penetrating the resin” regardless of whether the apertures are filled with other materials.

### Second Embodiment

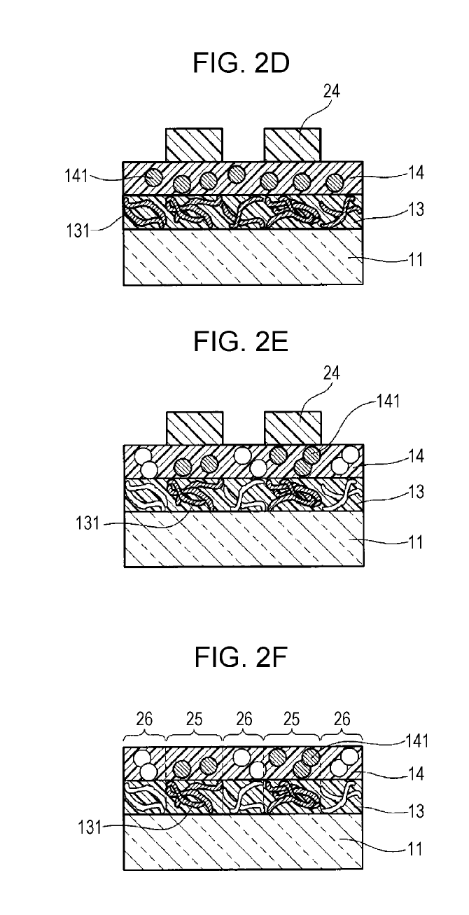

A touch panel 3 according to a second embodiment of the present disclosure is described below. The touch panel 3 includes a base material with a transparent conductive film that is obtained by patterning a conductive layer of a base material with a transparent conductive film into conductive portions and non-conductive portions as described in the first embodiment. FIG. 3 shows an example of the configuration of the touch panel 3.

The touch panel 3 is a capacitive touch panel and the upper side of FIG. 3 is the user side. The touch panel 3 includes a cover layer 31, first junction layer 32, first transparent electrode body 33, second junction layer 34, and second transparent electrode body 35 arranged in that order from the user side. The cover layer 31 is transparent and forms a touch surface. The first transparent electrode body 33 is a stack in which a base material 331, an electrode layer 332, and a protective layer 333 are stacked in that order. The electrode layer 332 and the protective layer 333 have a conductive pattern. The second transparent electrode body 35 is a stack in which a base material 351, an electrode layer 352, and a protective layer 353 are stacked in that order. The electrode layer 352 and the protective layer 353 have a conductive pattern. As shown in FIG. 3, the first transparent electrode body 33 and the second transparent electrode body 35 are arranged such that the base material 331 of the first transparent electrode body 33 and the protective layer 353 of the second transparent electrode body 35 are bonded to each other with the second junction layer 34 therebetween. The second junction layer 34 doubles as an insulating layer. However, the first transparent electrode body 33 and the second transparent electrode body 35 may be arranged such that the protective layer 333 of the first transparent electrode body 33 and the protective layer 353 of the second transparent electrode body 35 face each other with the second junction layer 34 therebetween.

The following material can be used in each of the first transparent electrode body 33 and the second transparent electrode body 35: a base material with a transparent conductive film that is obtained by patterning a conductive layer of a base material with a transparent conductive film into conductive portions and non-conductive portions as described in the first embodiment. That is, the base materials 331 and 351 correspond to the base material 11 described in the first embodiment. The electrode layers 332 and 352 correspond to a layer that is obtained by patterning the conductive layer 13 into the conductive portions 25 and the non-conductive portions 26 as described in the first embodiment. The protective layers 333 and 353 correspond to the protective layer 14 described in the first embodiment.

In the electrode layer 332 of the first transparent electrode body 33, a conductive portion (a portion where thin metal wires 131 are present) only is shown in a cross section of the touch panel 3 in FIG. 3. However, the electrode layer 332 of the first transparent electrode body 33 includes non-conductive portions. In the electrode layer 352 of the second transparent electrode body 35, conductive portions (portions where the thin metal wires 131 are present) and non-conductive portions (portions where the thin metal wires 131 have been removed) are shown in the cross section of the touch panel 3 in FIG. 3. Patterns of the electrode layers 332 and 352 that are shown in the cross section of the touch panel 3 in FIG. 3 are for exemplification only. The arrangement of electrode layers included in the touch panel 3 according to this embodiment is not particularly limited.

In the touch panel 3, the cover layer 31 and the first and second junction layers 32 and 34 are not particularly limited and may be a cover layer and junction layers, respectively, used in a known touch panel.

The touch panel 3 further includes other known members (not shown in FIG. 3), such as leads for electrically connecting electrode layers, necessary to function as a touch panel.

A touch panel according to the present disclosure is not limited to the touch panel 3 shown in FIG. 3 and may be a touch panel (for example, a resistive touch panel) having another configuration as long as a base material with a transparent conductive film that is obtained by patterning a conductive layer of a base material with a transparent conductive film into conductive portions and non-conductive portions as described in the first embodiment can be used.

### Third Embodiment

A solar cell 4 according to a third embodiment of the present disclosure is described below. The solar cell 4 includes a base material with a transparent conductive film that is obtained by patterning a conductive layer of a base material with a transparent conductive film into conductive portions and non-conductive portions as described in the first embodiment.

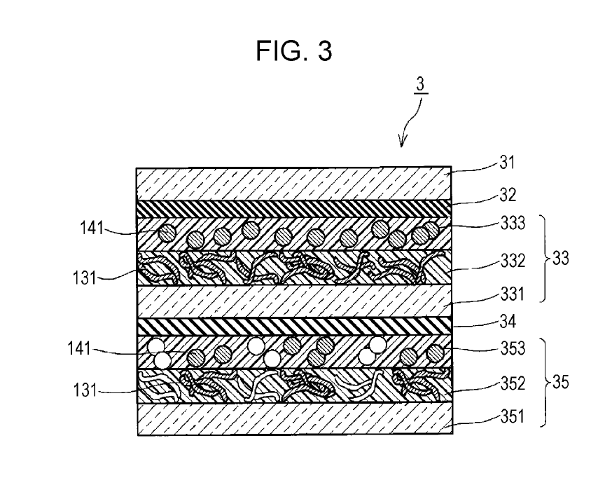

FIG. 4 shows an example of the configuration of the solar cell 4. The solar cell 4 is a dye-sensitized solar cell and converts light incident on the lower surface thereof into electricity as shown in FIG. 4. The solar cell 4 includes a base material 41, transparent electrode layer 42, protective layer 43, porous titanium dioxide layer 44, light-absorbing layer 45, charge transfer layer 46, counter electrode 47, and sealing substrate 48 arranged in that order from the bottom. The transparent electrode layer 42 has a conductive pattern. The light-absorbing layer 45 contains dye. The charge transfer layer 46 contains iodine. An insulating separator 49 may be placed on or above non-conductive portions of the conductive pattern. A combination of the base material 41, the transparent electrode layer 42, and the protective layer 43 is one obtained by patterning a base material with a transparent conductive film as described in the first embodiment and corresponds to the base material with a transparent conductive film including a conductive portion and a non-conductive portion shown in FIG. 2F.

In the solar cell 4, the base material 41, the titanium dioxide layer 44, the light-absorbing layer 45, the charge transfer layer 46, the counter electrode 47, the sealing substrate 48, and the separator 49 are not particularly limited and may contain materials used in known dye-sensitized solar cells.

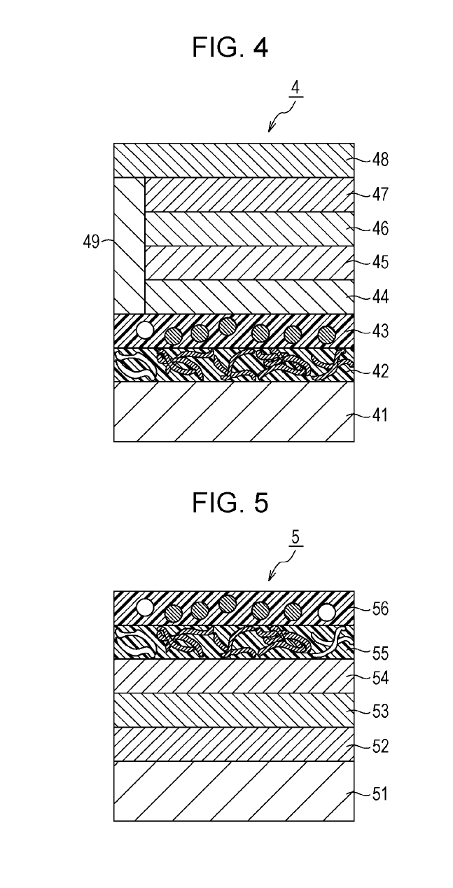

FIG. 5 shows an example of the configuration of a solar cell 5 according to another embodiment of the present disclosure. The solar cell 5 is a dye-sensitized solar cell and converts light incident on the lower surface thereof into electricity as shown in FIG. 5. The solar cell 5 includes a base material 51, counter electrode 52, n-type semiconductor layer 53, p-type semiconductor layer 54, transparent electrode layer 55, and protective layer 56 arranged in that order from the bottom. The transparent electrode layer 55 has a conductive pattern. A combination of the base material 51, the counter electrode 52, the n-type semiconductor layer 53, the p-type semiconductor layer 54, the transparent electrode layer 55, and the protective layer 56 is one obtained by patterning a base material with a transparent conductive film as described in the first embodiment and corresponds to the base material with a transparent conductive film including a conductive portion and a non-conductive portion shown in FIG. 2F.

In the solar cell 5, the base material 51, the counter electrode 52, the n-type semiconductor layer 53, and the p-type semiconductor layer 54 are not particularly limited and may contain materials used in known dye-sensitized solar cells.

A solar cell according to the present disclosure is not limited to the solar cell 4 shown in FIG. 4 or the solar cell 5 shown in FIG. 5 and may be a perovskite-type of solar cell having another configuration as long as a base material with a transparent conductive film that is obtained by patterning a base material with a transparent conductive film as described in the first embodiment can be used.

A base material with a transparent conductive film according to the present disclosure can be applied to the case where a plurality of separate solar cells are formed on a single base material.

### EXAMPLES

The present disclosure is further described below in detail with reference to examples. However, the present disclosure is not limited to the examples.

### Example 1

In Example 1, a base material with a transparent conductive film 1 was prepared as shown in FIG. 1. A base material 11 used was a transparent polyethylene terephthalate film (a thickness of 100 μm).

Next, a coated layer 16 was formed on a principal surface of the base material 11 as described below. To 10.8 parts by mass of an acrylic resin (U-6LPA, produced by Shin-Nakamura Chemical Co., Ltd.), 80.84 parts by mass of methyl ethyl ketone was added, followed by mixing, whereby the acrylic resin was dissolved in methyl ethyl ketone and a mixed solution was thereby prepared. To the mixed solution, 8.0 parts by mass of particles (a silica particle dispersion, containing methyl ethyl ketone as a dispersion medium, having a solid content of 15%) for preventing blocking were added, followed by mixing at room temperature. Furthermore, 0.36 parts by mass of a photopolymerization initiator (1-hydroxycyclohexyl phenyl ketone, Irgacure 184, produced by Ciba-Geigy Corporation) was added to the mixed solution, followed by well mixing and then stirring for 30 minutes in a 25° C. constant-temperature atmosphere, whereby a composition was obtained. The composition was applied to a principal surface of the base material 11 using Wire Bar Coater #10, was dried at room temperature for 2 minutes, was further dried at 80° C. for 3 minutes, and was then cured by applying ultraviolet rays (an ultraviolet intensity of 500 mJ/cm) to the composition, whereby the coated layer 16 was formed so as to have a refractive index of 1.49 and a thickness of 1,100 nm.

Next, an intermediate layer 15 was formed on a surface of the base material 11 that was opposite to the surface of the base material 11 that had the coated layer 16 thereon as described below.

To 1.8 parts by mass of the acrylic resin (U-6LPA, produced by Shin-Nakamura Chemical Co., Ltd.), 50.0 parts by mass of methyl ethyl ketone and 42.05 parts by mass of methyl isobutyl ketone were added, followed by mixing, whereby the acrylic resin was dissolved in methyl ethyl ketone and methyl isobutyl ketone and a mixed solution was thereby prepared. To this mixed solution, 6.0 parts by mass of particles (a zirconia dispersion, containing methyl ethyl ketone as a dispersion medium, having a solid content of 20%) for refractive index adjustment were added, followed by mixing at room temperature. Furthermore, 0.15 parts by mass of the photopolymerization initiator (1-hydroxycyclohexyl phenyl ketone, Irgacure 184, produced by Ciba-Geigy Corporation) was added to this mixed solution, followed by well mixing and then stirring for 30 minutes in a 25° C. constant-temperature atmosphere, whereby a composition for forming the intermediate layer 15 was prepared. The composition for forming the intermediate layer 15 was applied to a surface of the base material 11 using Wire Bar Coater #4, was dried at room temperature for 2 minutes, was further dried at 80° C. for 3 minutes, and was then cured by applying ultraviolet rays (an ultraviolet intensity of 500 mJ/cm) to the composition for forming the intermediate layer 15, whereby the intermediate layer 15 was formed so as to have a refractive index of 1.62 and a thickness of 120 nm.

Next, a conductive layer 13 was formed on the intermediate layer 15 as described below.

Ag nanowires (an average diameter of 50 nm and an average length of 15 μm) were prepared on the basis of the report “Preparation of Ag nanorods with high yield by polyol process, Materials chemistry and Physics, vol. 114, pp. 333-338”. A silver nanowire water dispersion with a solid content of 1.0% by mass was prepared using the Ag nanowires. Furthermore, a resin binder solution with a solid content of 1.0% by mass was prepared in such a manner that 1.0 part by mass of a cellulose resin (“SM”, produced by Shin-Etsu Chemical Co., Ltd., a solid content of 100% by mass) and 99 parts by mass of water were mixed together well while being heated at 80° C.

Next, 50 parts by mass of the silver nanowire water dispersion and 50 parts by mass of the resin binder solution were mixed together for 30 minutes in a 25° C. constant-temperature atmosphere, whereby a composition, having a solid content of 1.0% by mass, for forming the conductive layer 13 was prepared. The composition for forming the conductive layer 13 was applied to a surface of the intermediate layer 15 using Wire Bar Coater #10, was dried at room temperature for 3 minutes, and was then cured by drying the composition for forming the conductive layer 13 at 100° C. for 10 minutes, whereby the conductive layer 13 was formed so as to have a thickness of 120 nm.

Next, a protective layer 14 was formed on the conductive layer 13 as described below.

To 2.4 parts by mass of the acrylic resin (U-6LPA, produced by Shin-Nakamura Chemical Co., Ltd.), 50.0 parts by mass of methyl ethyl ketone and 44.45 parts by mass of methyl isobutyl ketone were added, followed by mixing, whereby the acrylic resin was dissolved in methyl ethyl ketone and methyl isobutyl ketone and a mixed solution was thereby prepared. To this mixed solution, 3.0 parts by mass of etchable particles (a zinc oxide dispersion, containing methyl ethyl ketone as a dispersion medium, having a solid content of 20%) were added, followed by mixing at room temperature. Furthermore, 0.15 parts by mass of the photopolymerization initiator (1-hydroxycyclohexyl phenyl ketone, Irgacure 184, produced by Ciba-Geigy Corporation) was added to this mixed solution, followed by well mixing and then stirring for 30 minutes in a 25° C. constant-temperature atmosphere, whereby a composition for forming the protective layer 14 was prepared. The composition for forming the protective layer 14 was applied to a surface of the conductive layer 13 using Wire Bar Coater #4, was dried at room temperature for 2 minutes, was further dried at 80° C. for 3 minutes, and was then cured by applying ultraviolet rays (an ultraviolet intensity of 500 mJ/cm) to the composition for forming the protective layer 14, whereby the protective layer 14 was formed so as to have a thickness of 120 nm.

The base material with a transparent conductive film 1 was prepared by the above procedure so as to have a structure in which the coated layer 16, the base material 11, the intermediate layer 15, the conductive layer 13, and the protective layer 14 were stacked in that order.

### Example 2

Cu nanowires (an average diameter of 100 nm and an average length of 10 μm) used as metal nanowires contained in the conductive layer 13 were prepared on the basis of the report “Aaron R. Rathmell, Benjamin J. Willey et al., The Growth Mechanism of CopperNanowires and Their Properties in Flexible, Transparent Conducting Films, Adv. Mater. 22 (2010) 3558-3563”. A Cu nanowire water dispersion with a solid content of 1.0% by mass was prepared using the Cu nanowires. A base material with a transparent conductive film 1 was prepared by the same method as that used in Example 1 except that the Cu nanowire water dispersion was used.

### Example 3

A base material with a transparent conductive film 1 was prepared by the same method as that used in Example 1 except that particles 141 contained in a protective layer 14 were prepared using an ITO dispersion (a solid content of 20%) containing isopropyl alcohol as a dispersion medium.

### Example 4

A protective layer 14 only was prepared by a method different from that used in Example 1. In particular, 50.0 parts by mass of methyl ethyl ketone and 42.05 parts by mass of methyl isobutyl ketone were added to 1.8 parts by mass of an acrylic resin (U-6LPA, produced by Shin-Nakamura Chemical Co., Ltd.), followed by mixing, whereby the acrylic resin was dissolved in methyl ethyl ketone and methyl isobutyl ketone and a mixed solution was thereby prepared. To this mixed solution, 6.0 parts by mass of etchable particles (a zinc oxide dispersion, containing methyl ethyl ketone as a dispersion medium, having a solid content of 20%) were added, followed by mixing at room temperature. Furthermore, 0.15 parts by mass of a photopolymerization initiator (1-hydroxycyclohexyl phenyl ketone, Irgacure 184, produced by Ciba-Geigy Corporation) was added to this mixed solution, followed by well mixing and then stirring for 30 minutes in a 25° C. constant-temperature atmosphere, whereby a composition for forming the protective layer 14 was prepared. This composition was applied to a surface of a base material 11 using Wire Bar Coater #6, was dried at room temperature for 2 minutes, was further dried at 80° C. for 3 minutes, and was then cured by applying ultraviolet rays (an ultraviolet intensity of 500 mJ/cm) to this composition, whereby the protective layer 14 was formed so as to have a thickness of 250 nm. A base material with a transparent conductive film 1 was prepared by the same method as that used in Example 1 except the protective layer 14.

### Comparative Example 1

A protective layer 14 only was prepared by a method different from that used in Example 1. In particular, 50.0 parts by mass of methyl ethyl ketone and 46.85 parts by mass of methyl isobutyl ketone were added to 3.0 parts by mass of an acrylic resin (U-6LPA, produced by Shin-Nakamura Chemical Co., Ltd.), followed by mixing, whereby the acrylic resin was dissolved in methyl ethyl ketone and methyl isobutyl ketone and a mixed solution was thereby prepared. To this mixed solution, 0.15 parts by mass of a photopolymerization initiator (1-hydroxycyclohexyl phenyl ketone, Irgacure 184, produced by Ciba-Geigy Corporation), followed by well mixing and then stirring for 30 minutes in a 25° C. constant-temperature atmosphere, whereby a composition for forming the protective layer 14 was prepared. This composition was applied to a surface of a base material 11 using Wire Bar Coater #4, was dried at room temperature for 2 minutes, was further dried at 80° C. for 3 minutes, and was then cured by applying ultraviolet rays (an ultraviolet intensity of 500 mJ/cm) to this composition, whereby the protective layer 14 was formed so as to have a thickness of 120 nm and so as not to contain any etchable particles. A base material with a transparent conductive film was prepared by the same method as that used in Example 1 except the protective layer 14.

### Comparative Example 2

A base material with a transparent conductive film was prepared by the same method as that used in Example 1 except that particles 141 contained in a protective layer 14 were prepared using an SiO₂ dispersion (a solid content of 20%) containing isopropyl alcohol as a dispersion medium.

### Comparative Example 3

A base material with a transparent conductive film was prepared by the same method as that used in Example 1 except that no protective layer 14 was formed.

### Pattern Formation Evaluation Test

The base materials with transparent conductive films prepared in Examples 1 to 4 and Comparative Examples 1 to 3 were subjected to an evaluation test in such a manner that the conductive layers were patterned as shown in FIGS. 2A to 2E. For etching, a sample taken from each base material with a transparent conductive film was immersed in a 35° C. etching solution (aqua regia) for 1 minute. The test results are shown in the table below.

### Haze Evaluation

The base materials with transparent conductive films prepared in Examples 1 to 4 and Comparative Examples 1 to 3 were measured for haze before etching treatment. Etched portions (non-conductive portions) and unetched portions (conductive portions) were measured for haze after etching treatment. In particular, a sample with a size of 5 cm×10 cm was prepared by cutting each of the base materials with a transparent conductive films prepared in Examples 1 to 4 and Comparative Examples 1 to 3. A half region of the sample was protected with a resist mask and the remaining half region of the sample was etched. Etching treatment was performed in such a manner that the sample was immersed in a 35° C. etching solution (aqua regia) for 1 minute. That is, the protected half region of the sample, which had a size of 5 cm×10 cm, was an unetched portion and the remaining half region of the sample was an etched portion. For the base materials with a transparent conductive films t prepared in Examples 1 to 4 and Comparative Examples 1 to 3, the etched portion and unetched portion of the sample were measured for haze using a hazemeter (NDH 2000, manufactured by Nippon Denshoku Industries Co., Ltd.). The measurement results are shown in the table 1.

### Surface Resistance Evaluation

The base materials with transparent conductive films prepared in Examples 1 to 4 and Comparative Examples 1 to 3 were measured for surface resistance before etching treatment. Etched portions (non-conductive portions) and unetched portions (conductive portions) were measured for surface resistance after etching treatment. In particular, a sample with a size of 5 cm×10 cm was prepared by cutting each of the base materials with a transparent conductive films prepared in Examples 1 to 4 and Comparative Examples 1 to 3. A half region of the sample was protected with a resist mask and the remaining half region of the sample was etched. Etching treatment was performed in such a manner that the sample was immersed in a 35° C. etching solution (aqua regia) for 1 minute. That is, the protected half region of the sample, which had a size of 5 cm×10 cm, was an unetched portion and the remaining half region of the sample was an etched portion. For the base materials with a transparent conductive films prepared in Examples 1 to 4 and Comparative Examples 1 to 3, the etched portion and unetched portion of the sample were measured for surface resistance using a non-contact resistivity measurement instrument (NC-10, manufactured by Napson Corporation) in an eddy-current mode and were evaluated using a surface resistivity meter (Hiresta IP MCP-HT260, manufactured by Mitsubishi Chemical Analytech Co., Ltd.) in the case of range over. The measurement results are shown in the table 1.

### Pattern Visibility Evaluation

Appearances of unetched portions (portions protected with resist masks, conductive portions) and etched portions (non-conductive portions) formed by etching treatment in the above pattern formation evaluation test were observed and the observation results were compared, whereby pattern visibility was evaluated as described below.

A: The visibility of a base material with a transparent conductive film does not vary before and after etching treatment or a pattern in a conductive layer is not observed after etching treatment.

B: The visibility of a base material with a transparent conductive film varies before and after etching treatment and a pattern in a conductive layer is observed after etching treatment.

The evaluation results of the base materials with a transparent conductive films prepared in Examples 1 to 4 and Comparative Examples 1 to 3 are shown in the table 1. From the table, in the base materials with a transparent conductive films prepared in Examples 1 to 4, it is confirmed that etched portions are insulated and unetched portions keep conductivity. Furthermore, in the base materials with transparent conductive films prepared in Examples 1 to 4, patterns in conductive layers are not observed. This is a good result. In contrast, in the base materials with a transparent conductive films prepared in Comparative Examples 1 and 2, it is confirmed that conductive layers are not sufficiently insulated by etching treatment. In the base materials with transparent conductive films prepared in Comparative Example 3, it can be confirmed that a conductive layer is damaged during patterning because there is no protective layer.

TABLE 1

| | | | | | | | Comparative | Comparative | Comparative |
|---|---|---|---|---|---|---|---|---|---|
| | | | Example 1 | Example 2 | Example 3 | Example 4 | Example 1 | Example 2 | Example 3 |
| Structure | Protective | Material for | ZnO | ZnO | ITO | ZnO | Resin only | SiO₂ | No protective |
| | layer | particles | | | | | | | layer |
| | | Content of | 20 | 20 | 20 | 40 | 0 | 20 | |
| | | particles | | | | | | | |
| | | (% by weight) | | | | | | | |
| | | Thickness (nm) | 120 | 120 | 120 | 250 | 120 | 120 | 0 |
| | Conductive | Thin metal | AgNW | CuNW | AgNW | AgNW | AgNW | AgNW | AgNW |
| | layer | wires | | | | | | | |
| | | Content of thin | 50 | 50 | 50 | 50 | 50 | 50 | 50 |
| | | metal wires | | | | | | | |
| | | (% by weight) | | | | | | | |
| | | Thickness (nm) | 120 | 120 | 120 | 120 | 120 | 120 | 120 |
| Evaluation | Haze | (%) | 1.0 | 0.8 | 0.9 | 1.4 | 1.0 | 1.1 | 1.5 |
| before etching | Surface | (Ω/square) | 40 | 46 | 38 | 40 | 42 | 42 | 40 |
| treatment | resistance | | | | | | | | |
| Evaluation of | Haze | (%) | 1.0 | 1.0 | 1.0 | 1.5 | 1.1 | 1.1 | 0.8 |
| etched portion | Surface | (Ω/square) | OR (>10¹³) | OR | OR | OR | 45 | 122 | OR |
| after etching | resistance | | | | | | | | |
| treatment | | | | | | | | | |
| Evaluation of | Haze | (%) | 1.0 | 0.9 | 1.0 | 1.4 | 1.1 | 1.2 | 1.4 |
| unetched | Surface | (Ω/square) | 42 | 45 | 40 | 40 | 42 | 44 | 236 |
| portion after | resistance | | | | | | | | |
| etching | | | | | | | | | |
| treatment | | | | | | | | | |

| | | | | | | | |
|---|---|---|---|---|---|---|---|
| Pattern visibility | A | A | A | A | A | A | B |
| Evaluation results of pattern formation | A pattern | A pattern | A pattern | A pattern | No pattern | No pattern | A film was |
| | could be | could be | could be | could be | could be | could be | damaged. |
| | formed. | formed. | formed. | formed. | formed. | formed. | |

A base material with a transparent conductive film according to the present disclosure is useful as an electrode for use in, for example, electronic devices, such as touch panels, solar cells, organic electroluminescent display panels, plasma display panels, liquid crystal display panels, and photoelectric conversion devices, needing to have optical properties.

What is claimed is:

1. A base material with a transparent conductive film on or above the base material, the transparent conductive film including: a conductive layer containing metal wires; and a protective layer being located on a side of the conductive layer and containing a resin and a particle, the side not opposing to the base material, wherein the particle is soluble in an acidic etching solution, and the resin is resistant to the acidic etching solution.

2. The base material with a transparent conductive film according to claim 1, wherein the metal wires are silver nanowires.

3. The base material with a transparent conductive film according to claim 1, wherein the metal wires are soluble in the acidic etching solution.

4. The base material with a transparent conductive film according to claim 1, wherein the particle includes at least one selected from the group consisting of SnO₂, ZnO, ITO, IZO, ATO, and In₂O₃.

5. A base material with a transparent conductive film on or above the base material, the transparent conductive film including: a conductive layer; and a protective layer being located on a side of the conductive layer and containing a resin, the side not opposing to the base material, wherein
the transparent conductive film includes a conductive portion and a non-conductive portion in an in-plane direction,
the conductive layer contains no metal wires in the conductive portion or contains less metal wires per unit area in the non-conductive portion than the conductive layer contains the metal wires per unit area in the conductive portion,
the protective layer contains a particle in the conductive portion, and includes an aperture penetrating the resin in a thickness direction in the non-conductive portion,
the particle is soluble in an acidic etching solution, and the resin is resistant to the acidic etching solution.

6. A touch panel comprising the base material with the transparent conductive film according to claim 5.

7. A solar cell comprising the base material with the transparent conductive film according to claim 5.

8. A method for manufacturing a base material with a transparent conductive film including a conductive portion and a non-conductive portion, comprising:
(a) preparing the base material with the transparent conductive film on or above the base material, the transparent conductive film including: a conductive layer containing metal wires; and a protective layer being located on a side of the conductive layer and containing a resin and a particle, the side not opposing to the base material, the particle being soluble in an acidic etching solution, the resin being resistant to the acidic etching solution;
(b) providing a mask having a pattern corresponding to the conductive portion on the protective layer;
(c) exposing the protective layer to an acidic etching solution through the mask; and
(d) removing the mask.
